(19) United States
(12) Patent Application Publication
(10) Pub. No.: US 2026/0359500 A1
(43) Pub. Date: Nov. 12, 2026

(54) METHODS AND AUTOMATED SYSTEMS FOR UNIT CELL GENERATION AND STRUCTURAL DESIGN

(71) Applicant: Toyota Motor Engineering & Manufacturing North America, Inc., Plano, TX (US)

(72) Inventors: Danny J. Lohan, West Bloomfield, MI (US); Ercan Mehmet Dede, Ann Arbor, MI (US); Stav Ashur, Urbana, IL (US)

(73) Assignee: Toyota Motor Engineering & Manufacturing North America, Inc., Plano, TX (US)

(21) Appl. No.: 19/200,803

(22) Filed: May 7, 2025

(51) Int. Cl. G06F 30/13

(52) U.S. Cl. CPC G06F 30/13

(57) ABSTRACT

A system for automated unit cell generation includes a processor and a memory communicably coupled to the processor and storing machine-readable instructions that, when executed by the processor, cause the processor to extract, using a polygonal boundary module, a plurality of polygonal boundary lines defining a plurality of polygon unit volume cells from image patterns of an input image. The processor also defines, using a rectangular boundary module, a plurality of lines defining a rectangular unit volume cell for each independent polygonal unit volume cell, and extracts, using a parameter extraction module, a key geometric parameter for each independent rectangular unit volume cell. The processor further simulates a physics-based property for each independent rectangular unit volume cell over a range of values for the key geometric parameter such that a physics-based property—key geometric parameter relationship is provided and stored in a look-up table.

### TECHNICAL FIELD

The present disclosure relates to structural design, and particularly to automated unit cell generation for structural design.

### BACKGROUND

Topology optimization frameworks, such as classical methods using predefined geometric shapes for modeling structures within a continuum, have traditionally depended on the predefined geometric shapes to derive analytical physics-based properties that are important for optimizing macro-scale performance. And such methods typically rely on unit cell structures with regular geometric shapes such as circles or squares, for which physical properties can be analytically derived. However, the use of such regular geometric shapes fails to capture the complexity and diversity found in naturally occurring patterns which have evolved through natural selection to accomplish defined functions, and thereby offer a rich source for enhanced design strategies. In addition, current methodologies that take advantage of such naturally occurring patterns predominantly use manual interpretation of emergent patterns, which may inadvertently result in inaccuracies regarding shape and size, and thereby compromise the reliability of physics performance analyses. In addition, this manual approach is both time-consuming and susceptible to human bias.

The present disclosure addresses issues related to defining structures based on naturally occurring patterns and other issues related to design strategies.

### SUMMARY

This section provides a general summary of the disclosure and is not a comprehensive disclosure of its full scope or all of its features.

In one form of the present disclosure, a system for automated unit cell generation includes a processor and a memory communicably coupled to the processor and storing machine-readable instructions that, when executed by the processor, cause the processor to extract, using a boundary module, a plurality of polygonal boundary lines defining a plurality of polygon unit volume cells from image patterns of an input image. The processor also defines, using a rectangular boundary module, a plurality of lines defining a rectangular unit volume cell for each independent polygonal unit volume cell, and extracts, using a parameter extraction module, a key geometric parameter for each independent rectangular unit volume cell. The processor further simulates, using a simulation module, a physics-based property for each independent rectangular unit volume cell over a range of the key geometric parameter such that a physics-based property—key geometric parameter relationship is provided, and stores the physics-based property—key geometric parameter relationship in a look-up table.

In another form of the present disclosure, a method of automated unit cell generation includes extracting unit volume cells from image patterns of an input image using a shape boundary algorithm, defining a rectangular unit volume cell for each independent unit volume cell, extracting a key geometric parameter for each independent rectangular unit volume cell, identifying a range of key geometric parameter values, simulating a physics-based property for each rectangular unit volume cell over the range of key geometric parameter values such that a physics-based property—key geometric parameter relationship is provided, and storing the physics-based property—key geometric parameter relationship in a look table.

Further areas of applicability and various methods of enhancing the above technology will become apparent from the description provided herein. The description and specific examples in this summary are intended for purposes of illustration only and are not intended to limit the scope of the present disclosure.

### BRIEF DESCRIPTION OF THE DRAWINGS

The present teachings will become more fully understood from the detailed description and the accompanying drawings, wherein:

FIG. 1 shows a block diagram for a system of automatic cell generation according to the teachings of the present disclosure;

FIG. 2 shows an input image with polygonal boundary lines defining a plurality of polygonal unit volume cells according to the teachings of the present disclosure;

FIG. 3. is the input image in FIG. 2 with rectangle lines defining a plurality of rectangular polygonal unit volume cells according to the teachings of the present disclosure;

FIG. 4 is an isolated view of a unit volume cell from FIGS. 2 and 3 according to the teachings of the present disclosure;

FIG. 4A is a graphical plot of parameter extraction of the area of the rectangular polygonal unit volume cell boundaries in FIG. 3;

FIG. 4B is a graphical plot of parameter extraction for distance from an obstruction to polygonal unit volume cell boundaries in FIG. 3;

FIG. 4C is a graphical plot of parameter extraction for distance from an obstruction to rectangular polygonal unit volume cell boundaries in FIG. 3;

FIG. 5 is a graphical plot of permeability of a unit volume cell as a function of channel size for different fluids flowing through the rectangular unit volume cell;

FIG. 6 is an example of a representative fluid flow where a distribution of material permeability in a designed domain is represented by differing levels of grayscale;

FIG. 7 is an explicit physical structure mapped from the design domain with the fluid flow in FIG. 6; and

FIG. 8 is a flow diagram of a method for automatic cell generation according to the teachings of the present disclosure.

It should be noted that the figures set forth herein are intended to exemplify the general characteristics of the methods and devices among those of the present technology, for the purpose of the description of certain aspects. The figures may not precisely reflect the characteristics of any given aspect and are not necessarily intended to define or limit specific forms or variations within the scope of this technology.

### DETAILED DESCRIPTION

The present disclosure provides systems and methods for automated unit volume cell generation from a two dimensional (2D) image, e.g., a 2D image of a naturally occurring pattern in nature (also referred to herein as “nature pattern” or “nature patterns”). Also, the unit volume cells are for the development of physics-based property—unit cell geometric parameter relationships that can be stored in a look-up table and used for design of physical structures. In this manner, previous complex simulations of nature patterns are simplified and/or manual interpretation of nature patterns is replaced with an automated process.

The systems include a processor and a memory storing machine-readable instructions that command or direct the processor to execute various functions as described herein. In some variations, the processor, directed by a polygonal boundary module, extracts a plurality of polygonal boundary lines from an image pattern in an input image such that polygonal unit volume cells are defined. As used herein, the terms “polygon” and “polygonal” are defined as polygon shapes that are not and exclude rectangles and the phrase “polygonal boundary lines” refers to lines that bound and define a polygon that is not a rectangle. The systems also include a rectangular boundary module that directs the processor to extract rectangular lines that define rectangular unit volume cells for each independent polygonal unit volume cell. Accordingly, the systems automatically define rectangular unit volume cells for image patterns of an input image of a naturally occurring pattern. As used herein, the phrase “unit volume cell” refers to unit cell of a 2D image with a predefined depth into the plane of the 2D image.

The systems can include a parameter extraction module that directs the processor to extract key geometric parameters for each independent polygonal unit volume cell and/or each independent rectangular unit volume cell defined from an image pattern, and a simulation module that directs the processor to simulate a physics-based property for the independent rectangular unit volume cells over a range of values for the key geometric parameters. As used herein, the phrase “key geometric parameter” refers to a physics relevant geometric measurement or other geometric parameter interpretable from 2D images. Non-limiting examples for a key geometric parameter include effective length, area, volume, radius of curvature, and distribution, among others. The simulation provides one or more relationships between the physics-based property and the range of values for key geometric parameters, the physics-based property—key geometric parameter relationships can be stored in a look-up table, and the look-up table used in designing a physical structure. In this manner automated unit volume cell generation according to the teachings of the present disclosure significantly reduces the computation complexity and computation time for the design of physical structures based on nature patterns.

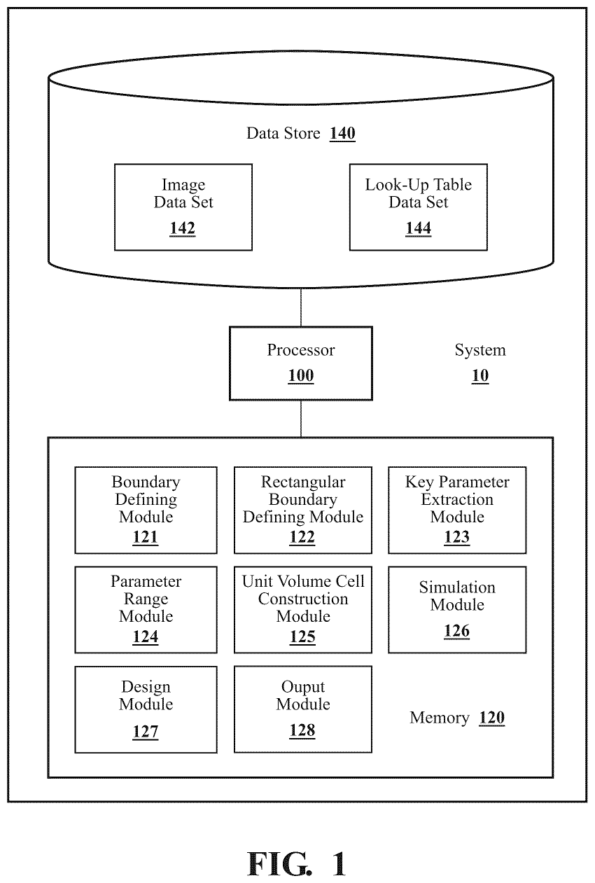

Referring to FIG. 1, a system for automated unit cell generation 10 (also referred to herein simply as “system 10”) is shown. The system 10 includes a processor 100, a memory 120, and a data store 140. The memory 120 can include a polygonal boundary module 121, a rectangular boundary module 122, a key parameter extraction module 123, a parameter range module 124, a unit volume cell construction module 125, a simulation module 126, a design module 127, and an output module 128 (referred to herein collectively as “modules 121-128”). The memory 120 is a random-access memory (RAM), read-only memory (ROM), a hard-disk drive, a flash memory, or other suitable memory for storing the modules 121-128. Also, the modules 121-128 are, for example, computer-readable instructions that when executed by the processor 100 cause the processor(s) to perform the various functions disclosed herein.

In some variations the data store 140 is a database, e.g., an electronic data structure stored in the memory 120 or another data store. Also, in at least one variation the data store 140 in the form of a database is configured with routines that can be executed by the processor 100 for analyzing stored data, providing stored data, organizing stored data, and the like. Accordingly, in some variations the data store 140 stores data used by one or more of the modules 121-128. For example, in some variations the data store 140 stores an image data set 142 and a look-up table data set 144.

In some variations, the image data set 142 includes images of natural occurring patterns such as leaf venation, river basins, honeycombs, sand dunes, snowflakes, bubbles, and dried mud, among others. In at least one variation, the image data set 142 includes images of non-natural human generated patterns such as images generated using a pattern generation algorithm such that systems and methods disclosed herein capture the generation capability of the algorithm for physics based applications.

The look-up table data set 144 includes data in one or more formats such as tabulated data, graphs, and equations, among others. In some variations, the data is provided to the look-up table data set 144 by the output module 128 as explained in greater detail below. In at least one variation, data is provided (input) to the look-up table data set 144 manually input by a user. And in some variations, data is transferred (copied) to the look-up table data set 144 from an external data set.

The processor 100 executes machine-readable instructions stored in the memory 120 and coordinates operations of the various modules 121-128. Accordingly, the processor 100 ensures seamless data processing and task execution, while the memory 120 stores instructions and facilitates efficient communication between the processor 100 and the other components of the system 10. Also, it should be understood that the processor 100 can be part of the system 10, or in the alternative, the system 10 can access the processor 100 through a data bus or another communication path.

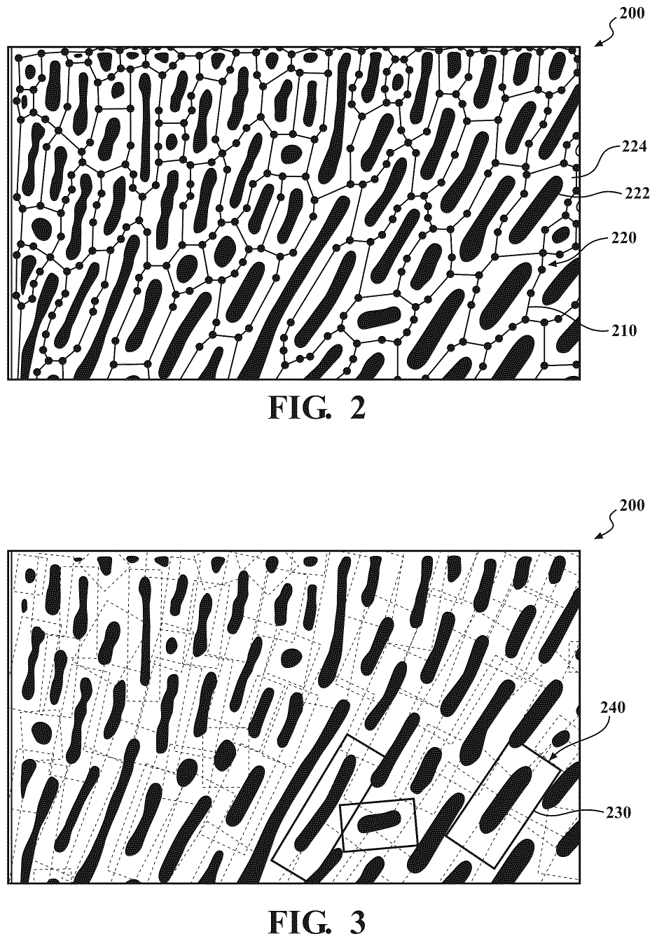

During operation of the system 10, and with reference to FIG. 2, the polygonal boundary module 121 extracts polygonal boundary lines 210 from an input image 200, e.g., an image stored in the image data set 142, such that polygonal unit volume cells 220 of or for the input image 200 are defined. The polygonal boundary module 121 can include and instruct the processor 100 to define the polygonal boundary lines 210 using algorithms such as a skeletonization image processing algorithm and/or a Voronoi image processing algorithm, among others. In some variations, each of the polygonal unit volume cells 220 includes an obstruction region 222 and a flow region 224, and the polygonal boundary module 121 extracts polygonal boundary lines 210 around each obstruction region 222 is illustrated in FIG. 2.

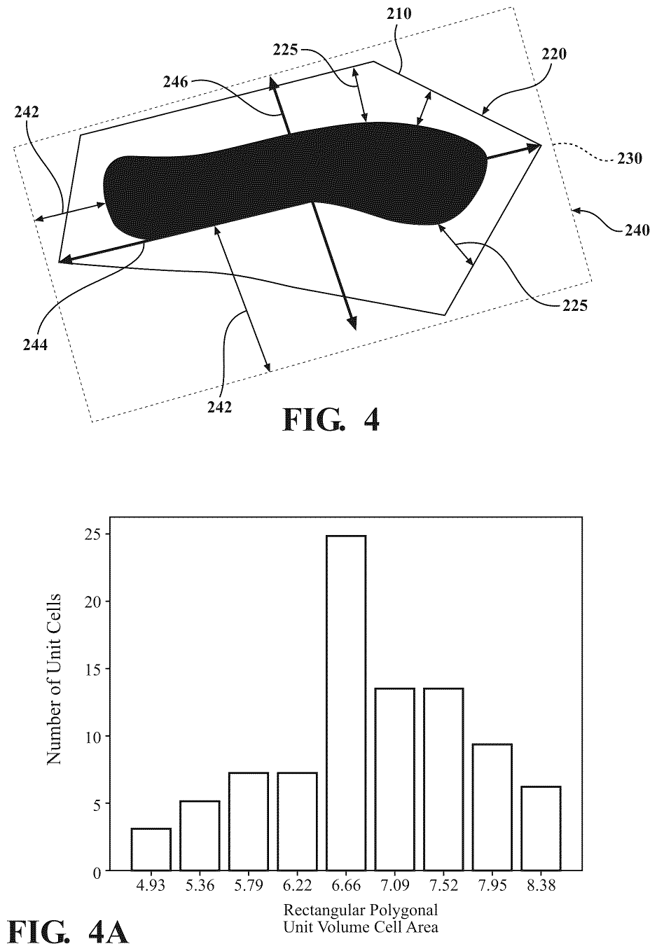

With reference to FIG. 3, the rectangular boundary module 122 extracts rectangle boundary lines 230 to define rectangular unit volume cells 240 for each independent polygonal unit volume cell 220. As used herein, the phrase “independent polygonal unit volume cell” refers to any polygonal unit volume cell 220 with a disconnected obstruction region 222, i.e., an obstruction region 222 completely bounded within a polygonal unit volume cell 220.

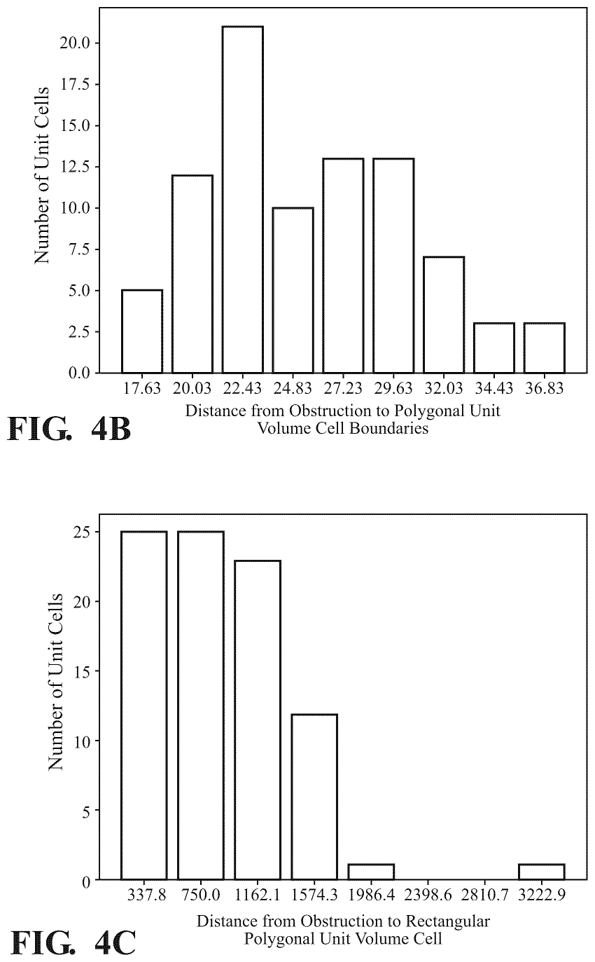

Referring to FIG. 4, an isolated view of a polygonal unit volume cell 220 automatically generated by the polygonal boundary module 121 and a corresponding rectangular unit volume cell 240 automatically generated by the rectangular boundary module 122 is shown. As shown in FIG. 4, the polygonal unit volume cell 220 is defined by the polygonal boundary lines 210 and the rectangular unit volume cell 240 is defined by the rectangle boundary lines 230.

FIG. 4 also illustrates extraction of key geometric parameters via the key parameter extraction module 123 for the polygonal unit volume cell 220 and the rectangular unit volume cell 240. For example, the double-headed arrows 225 (also referred to herein as key geometric parameter 225) represent the shortest distance from points on the obstruction region 222 to the polygonal unit volume cell 220, the double-headed arrows 242 (also referred to herein as key geometric parameter 242) represent the shortest distance from points on the obstruction region 222 to the rectangular unit volume cell 240, and the double-headed arrows 244, 246 (also referred to herein as key geometric parameters 244, 246) represent the length and width, respectively, of the rectangular unit volume cell 240.

It should be understood that key parameter extraction module 123 directs the processor 100 to extract the key geometric parameters 225, 242, 244, 246 from the image pattern of the input image 200. It should also be understood that other key geometric parameters not illustrated in FIG. 4 can be extracted by the key parameter extraction module 123 and/or that additional key geometric parameters can be derived or calculated from key geometric parameters extracted by the key parameter extraction module 123. For example, key geometric parameters such as channel size of a given rectangular unit volume cell 240, hydraulic diameter of a given rectangular unit volume cell 240, and porosity of a given rectangular unit volume cell 240, among others, can be derived from the key geometric parameters extracted by the key parameter extraction module 123.

Referring to FIGS. 4A-4C, histograms for the product of key geometric parameters 244 and 246 (FIG. 4A), the key geometric parameter 225 (FIG. 4B), and the key geometric parameter 242 are shown for the image pattern in FIG. 3. That is, the key parameter extraction module 123 directs the processor 100 to extract and plot the key geometric parameters 225, 242, 244, 246 for each independent rectangular unit volume cell 240 such that ranges (i.e., a range of values) of the key geometric parameters 225, 242, 244, 246 are easily identified and used for simulation. In some variations, the parameter range module 124 directs the processor to identify and select a range of values for one or more of the key geometric parameters 225, 242, 244,246 as a function of a predefined criteria (e.g., +/−10% of a maximum value, +/−20% of maximum value, etc.).

In some variations, the unit volume cell construction module 125 constructs 3D CAD unit volume cells (not shown) for each independent rectangular unit volume cell 240 and the simulation module 126 simulates the independent rectangular unit volume cells 240 for a physics-based property (e.g., permeability) using the range of values for one or more the key geometric parameters 225, 242, 244, 246, mentioned above. For example, the simulation module 126 directs the processor 100 to simulate a fluid, an electromagnetic wave, and/or a sound wave, flowing or propagating through the rectangular unit volume cell 240, having a predefined depth (y-direction), from an inlet side to an outlet side as illustrating by the labeled arrows in FIG. 4.

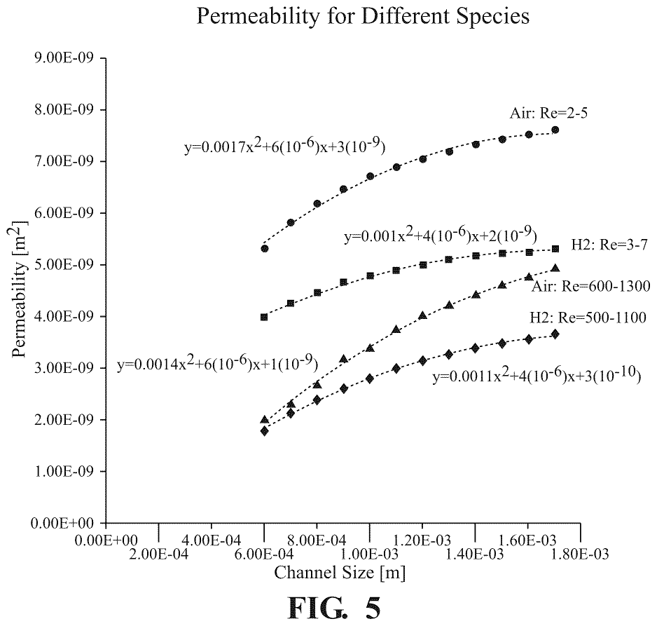

Referring to FIG. 5, the results of such a simulation is shown in which the simulation module 126 simulated the permeability for the flow of air and hydrogen (H₂) with different flow rate conditions through a 3D CAD generated unit volume cell (not shown) across a range of values for a key geometric parameter referred to as “channel size.” The flow of air with a Reynolds number (Re) between 2-5, the flow of air with a Re between 600-1300, the flow of H2 with a Re between 3-7, and the flow of H2 with a Re between 500-1100, through the 3D CAD generated unit volume cell with a channel size between 0.8 millimeters (mm) to 1.7 mm was simulated. And in some variations, the simulation module 126 directs the processor to “fit” the simulated data with one or more equations (e.g., binomial equations shown in FIG. 5) and the output module 128 directs the processor 100 to save the equations in the look-up table data set 144.

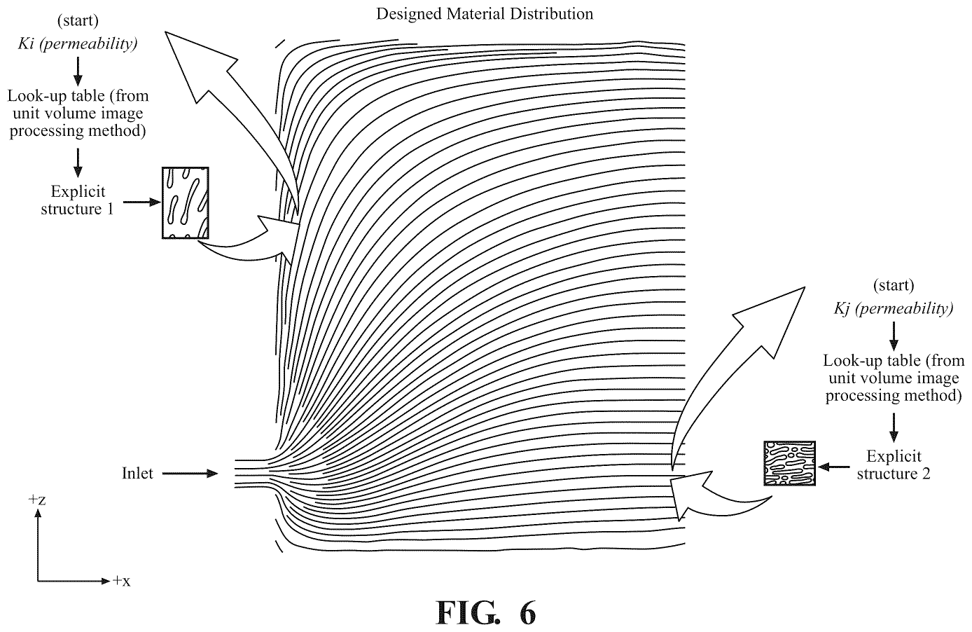

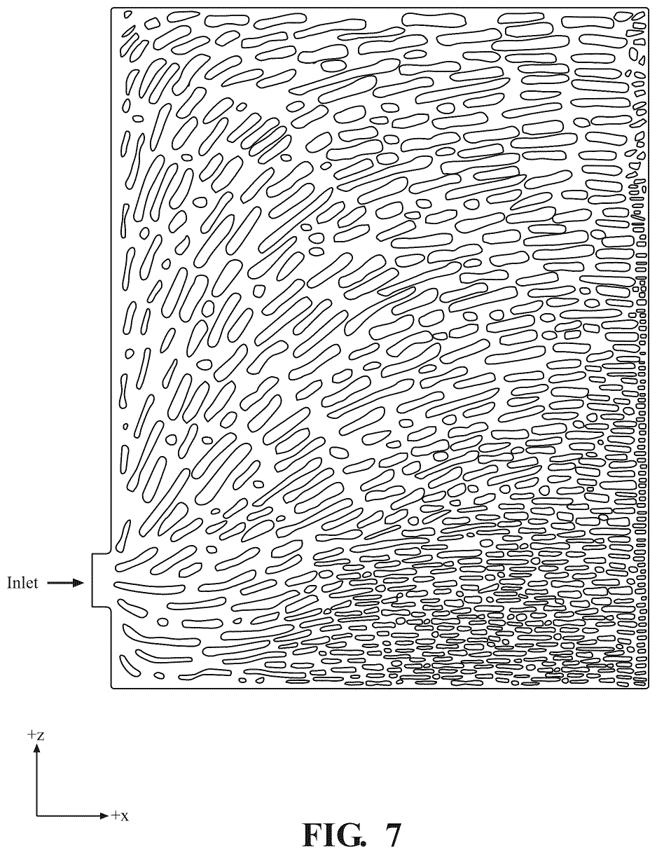

Referring now to FIGS. 6-7, design of a physical structure using the system 10 is illustrated. A material distribution design with a fluid flow inlet is shown in FIG. 6 and a resulting physical structure shown in FIG. 7 in which obstruction regions (oblong shapes) shown in the figures are not shaded in black for clarity). The material distribution design can be any kind or type of fluid, electromagnetic wave, or sound wave distribution design, including but not limited to designs for or related to an electronics heat sink, an electrolyzer, a fuel cell, a structural composite, an electromagnetic metasurface, and/or other physical system where fluids, electromagnetic waves, or sound waves flow and/or propagate therethrough.

Two example locations in the material distribution design in FIG. 6 with a known or desired permeability are highlighted, and given the known permeability, the design module 127 directs the processor 100 to use the data stored the look-up table data set 144 to generate an explicit structure for each example location as illustrated in FIG. 6. In addition, the system 10 generates an explicit structure for all of the permeability values in the material distribution design shown in FIG. 6 and thereby generates a complete physical structure as shown in FIG. 7. It should be understood that while FIG. 1 illustrates the design module 127 being part of the system 10, in some variations, the system 10 does not include the design module 127. In such variations, the data in the look-up table data set 144 can be provided to a design module that is separate from the system 10 such that physical structures can be designed with a significant reduction in computation time.

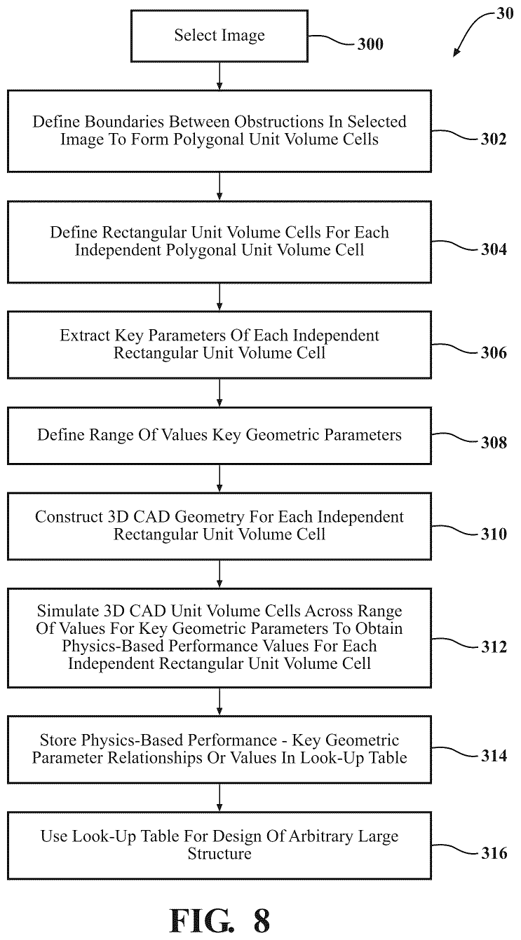

Referring to FIG. 8, a method 30 for automated unit volume cell generation is shown. At 300, the method 30 selects an input image at 300 (e.g., from the image data set 142), which serves as input from which the unit volume cells are subsequently extracted and analyzed. The method 30 delineates or defines boundaries between obstructions in the input image selected at 302 and thereby extracts polygonal unit volume cells in the image pattern. At 304 the method 30 extracts rectangular unit volume cells for each of the independent polygonal unit volume cells and extracts key geometric parameters for each of the independent rectangular unit volume cells at 306. A range of values for the key geometric parameters is defined at 308 and a 3D CAD geometry for each independent rectangular unit volume cell is constructed at 310.

The method 30 proceeds to 312 where the 3D CAD unit volume cells are simulated across a range of values for the key geometric parameters for a physics-based property such that physics-based performance values of the physics-based property are simulated. The simulation at 312 provides physics-based performance—key geometric parameter relationships for the image pattern in the input image, which is stored in a look-up table at 314. In some variations, the method proceeds to 316 where the physics-based performance—key geometric parameter relationships are used in the design of an arbitrary large physical structure.

In view of the above disclosure, it should be understood that the systems and methods disclosed herein provide for the automated design of physical structures via the capture of the complexity and diversity found in naturally occurring patterns which have evolved through natural selection for design of physical structures without manual interpretation of emergent patterns, which may inadvertently result in inaccuracies regarding shape and size, and thereby compromise the reliability of physics performance analyses. The systems and methods disclosed herein also provide for such automated design of physical structures in a time and cost efficient manner.

Further areas of applicability and various methods of enhancing the above technology will become apparent from the description provided herein. The description and specific examples in this summary are intended for purposes of illustration only and are not intended to limit the scope of the present disclosure.

The preceding description is merely illustrative in nature and is in no way intended to limit the disclosure, its application, or its uses. Work of the presently named inventors, to the extent it may be described in the background section, as well as aspects of the description that may not otherwise qualify as prior art at the time of filing, are neither expressly nor impliedly admitted as prior art against the present technology.

The flowcharts and block diagrams in the figures illustrate the architecture, functionality, and operation of possible implementations of systems, methods, and computer program products according to various embodiments. In this regard, each block in the flowcharts or block diagrams may represent a module, segment, or portion of code, which comprises one or more executable instructions for implementing the specified logical function(s). It should also be noted that, in some alternative implementations, the functions noted in the block may occur out of the order noted in the figures. For example, two blocks shown in succession may, in fact, be executed substantially concurrently, or the blocks may sometimes be executed in the reverse order, depending upon the functionality involved.

The systems, components and/or processes described above can be realized in hardware or a combination of hardware and software and can be realized in a centralized fashion in one processing system or in a distributed fashion where different elements are spread across several interconnected processing systems. The systems, components and/or processes also can be embedded in a computer-readable storage, such as a computer program product or other data program storage device, readable by a machine, tangibly embodying a program of instructions executable by the machine to perform methods and processes described herein. These elements also can be embedded in an application product which comprises the features enabling the implementation of the methods described herein and, which when loaded in a processing system, is able to carry out these methods.

Furthermore, arrangements described herein may take the form of a computer program product embodied in one or more computer-readable media having computer-readable program code embodied, e.g., stored, thereon. The phrase “computer-readable storage medium” means a non-transitory storage medium. A computer-readable storage medium may be, for example, an electronic, magnetic, optical, electromagnetic, infrared, or semiconductor system, apparatus, or device, or any suitable combination of the foregoing. A non-exhaustive list of the computer-readable storage medium can include the following: a portable computer diskette, a hard disk drive (HDD), a solid-state drive (SSD), a read-only memory (ROM), an erasable programmable read-only memory (EPROM or Flash memory), a portable compact disc read-only memory (CD-ROM), a digital versatile disc (DVD), an optical storage device, a magnetic storage device, or a combination of the foregoing. In the context of this document, a computer-readable storage medium is, for example, a tangible medium that stores a program for use by or in connection with an instruction execution system or device.

Computer program code for carrying out operations for aspects of the present arrangements may be written in any combination of one or more programming languages, including an object-oriented programming language such as Java™, Smalltalk, C++ or the like and conventional procedural programming languages, such as the “C” programming language or similar programming languages. The program code may execute entirely on the user's computer, partly on the user's computer, as a stand-alone software package, partly on the user's computer and partly on a remote computer, or entirely on the remote computer or server. In the latter scenario, the remote computer may be connected to the user's computer through a network, including a local area network (LAN) or a wide area network (WAN), or the connection may be made to an external computer (for example, through the Internet using an Internet Service Provider).

As used herein, the phrase at least one of A, B, and C should be construed to mean a logical (A or B or C), using a non-exclusive logical “or.” It should be understood that the various steps within a method may be executed in different order without altering the principles of the present disclosure.

The headings (such as “Background” and “Summary”) and sub-headings used herein are intended only for the general organization of topics within the present disclosure and are not intended to limit the disclosure of the technology or any aspect thereof. The recitation of multiple variations or forms having stated features is not intended to exclude other variations or forms having additional features, or other variations or forms incorporating different combinations of the stated features.

The terms “a” and “an,” as used herein, are defined as one or more than one. The term “plurality,” as used herein, is defined as two or more than two. The term “another,” as used herein, is defined as at least a second or more. The terms “including” and/or “having,” as used herein, are defined as comprising (i.e., open language). The phrase “at least one of . . . and . . . ” as used herein refers to and encompasses any and all possible combinations of one or more of the associated listed items. As an example, the phrase “at least one of A, B, and C” includes A only, B only, C only, or any combination thereof (e.g., AB, AC, BC, or ABC).

As used herein, the terms “comprise” and “include” and their variants are intended to be non-limiting, such that recitation of items in succession or a list is not to the exclusion of other like items that may also be useful in the devices and methods of this technology. Similarly, the terms “can” and “may” and their variants are intended to be non-limiting, such that recitation that a form or variation can or may comprise certain elements or features does not exclude other forms or variations of the present technology that do not contain those elements or features.

The broad teachings of the present disclosure can be implemented in a variety of forms. Therefore, while this disclosure includes particular examples, the true scope of the disclosure should not be so limited since other modifications will become apparent to the skilled practitioner upon a study of the specification and the following claims. Reference herein to one variation, or various variations means that a particular feature, structure, or characteristic described in connection with a form or variation or particular system is included in at least one variation or form. The appearances of the phrase “in one variation” (or variations thereof) are not necessarily referring to the same variation or form. It should also be understood that the various method steps discussed herein do not have to be conducted in the same order as depicted, and not each method step is required in each variation or form.

The foregoing description of the forms and variations has been provided for purposes of illustration and description. It is not intended to be exhaustive or to limit the disclosure. Individual elements or features of a particular form or variation are generally not limited to that particular form or variation, but, where applicable, are interchangeable and can be used in a selected form or variation, even if not specifically shown or described. The same may also be varied in many ways. Such variations should not be regarded as a departure from the disclosure, and all such modifications are intended to be included within the scope of the disclosure.

What is claimed is:

1. A system for automated unit cell generation, the system comprising:
a data store, a processor, and a memory communicably coupled to the processor and storing machine-readable instructions that, when executed by the processor, cause the processor to:
extract plurality of polygonal boundary lines defining a plurality of polygon unit volume cells from image patterns of an input image;
define a plurality of lines defining a rectangular unit volume cell for each independent polygonal unit volume cells;
extract a key geometric parameter for each independent rectangular unit volume cell;
simulate a physics-based property for at least one of the independent rectangular unit volume cells over a range of values for the key geometric parameter such that a physics-based property—key geometric parameter relationship is provided; and
store the physics-based property—key geometric parameter relationship in a look-up table data set.

2. The system according to claim 1 further comprising a polygonal boundary module to direct the processor to extract the plurality of polygonal boundary lines using an algorithm selected from the group consisting of a skeletonization image processing algorithm and a Voronoi image processing algorithm.

3. The system according to claim 1, wherein the unit volume cells each comprise an obstruction region within a flow region.

4. The system according to claim 1, wherein the key geometric parameter is selected from the group consisting of size of a rectangular unit volume cell, hydraulic diameter of a rectangular unit volume cell, and porosity of a rectangular unit volume cell.

5. The system according to claim 1 further comprising a unit volume cell construction module configured to direct the processor to construct a 3D CAD unit volume for each of the independent rectangular unit volume cell.

6. The system according to claim 5 further comprising a simulation module configured to direct the processor to simulate the physics-based property over the range of values of the key geometric parameter for the 3D CAD unit volume for each of the independent rectangular unit volume cells.

7. The system according to claim 6, wherein the physics-based property is permeability.

8. The system according to claim 1, wherein the physics-based property—key geometric parameter relationship is selected from the group consisting of the physics-based property as a function of size of the at least one independent rectangular unit volume cells, the physics-based property as a function of hydraulic diameter of the at least one independent rectangular unit volume cells, and the physics-based property as a function of porosity of the at least one independent rectangular unit volume cells.

9. A system for automated unit cell generation, the system comprising:
a data store, a processor, and a memory communicably coupled to the processor and storing machine-readable instructions that, when executed by the processor, cause the processor to:
extract, via a polygonal boundary module directing the processor, plurality of polygonal boundary lines defining a plurality of polygon unit volume cells from image patterns of an input image;
define, via a rectangular boundary module directing the processor, a plurality of lines defining a rectangular unit volume cell for each independent polygonal unit volume cell;
extract, via a key parameter extraction module directing the processor, a key geometric parameter for each independent rectangular unit volume cell;
simulate, via a simulation module directing the processor, a physics-based property for at least one of the independent rectangular unit volume cell over a range of values for the key geometric parameter such that a physics-based property—key geometric parameter relationship is provided; and
store the physics-based property—key geometric parameter relationship in a look-up table data set.

10. The system according to claim 9, wherein the polygonal boundary module comprises at least one of a skeletonization image processing algorithm and a Voronoi image processing algorithm.

11. The system according to claim 9, wherein the unit volume cells each comprise an obstruction region within a flow region.

12. The system according to claim 9, wherein the key geometric parameter is selected from the group consisting of size of a rectangular unit volume cell, hydraulic diameter of a rectangular unit volume cell, and porosity of a rectangular unit volume cell.

13. A method of automated unit cell generation, the method comprising:
extracting polygonal unit volume cells from image patterns of an input image;
defining a rectangular unit volume cell for each independent unit volume cell;
extracting a key geometric parameter for each independent rectangular unit volume cell;
identifying a range of values for the key geometric parameter;
simulating a physics-based property for each rectangular unit volume cell over the range of values for the key geometric parameter such that a physics-based property—key geometric parameter relationship is provided; and
storing the physics-based property—key geometric parameter relationship in a look table.

14. The method according to claim 13, wherein extracting the polygonal unit volume cells comprises using at least one of a skeletonization image processing algorithm and a Voronoi image processing algorithm.

15. The method according to claim 13, wherein the extracted polygonal unit volume cells each comprise an obstruction region within a flow region.

16. The method according to claim 13, wherein the key geometric parameter is selected from the group consisting of size of a rectangular unit volume cell, hydraulic diameter of a rectangular unit volume cell, and porosity of a rectangular unit volume cell.

17. The method according to claim 13 further comprising constructing a 3D CAD unit volume cell for each independent rectangular unit volume cell.

18. The method according to claim 17 wherein simulating the physics-based property over the range of values for the key geometric parameter comprises simulating the physics-based property over the range of values for the key geometric parameter for the 3D CAD unit volume cell for each of the independent rectangular unit volume cells.

19. The method according to claim 18, wherein the physics-based property is permeability.

20. The method according to claim 13, wherein the physics-based property—key geometric parameter relationship is selected from the group consisting of the physics-based property as a function of size of a rectangular unit volume cell, the physics-based property as a function of hydraulic diameter of a rectangular unit volume cell, and the physics-based property as a function of porosity of a rectangular unit volume cell.
